(19) United States
(12) Patent Application Publication
(10) Pub. No.: US 2005/0015213 A1
(43) Pub. Date: Jan. 20, 2005

(54) Method and apparatus for testing an electronic device

(76) Inventors: Kevin Somervill, Newport News, VA (US); Andrew Chau, Sacramento, CA (US); Robert William Dobbs, Granite Bay, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/619,912

(22) Filed: Jul. 15, 2003

(51) Int. Cl. G01R 31/00

(52) U.S. Cl. 702/117

(57) ABSTRACT

A method of testing an electronic device. A test pattern is transferred between a first data controller coupled to a first data interface and a second data controller coupled to a second data interface via an element coupling the first and second data interfaces. The test pattern is received and examined.

### TECHNICAL FIELD

The present invention relates to the field of testing electronic devices. Specifically, embodiments of the present invention relate to methods and devices for testing an electronic device by using a bridge between multiple data interfaces of the electronic device.

### BACKGROUND ART

As electronic devices such as Application Specific Integrated Circuits (ASICs), microprocessors, etc. have become more complex, the cost and difficulty of testing such devices has increased. Boundary scan methodology was developed as a way to simplify the testing of an electronic device, referred to herein as a device under test (DUT), that complies with boundary scan requirements. Boundary scan methodology comprises the use of a scan chain or loop to transfer test data from a test controller to at least one DUT and back to the test controller. Special hardware, such as boundary cells and dedicated pins, may be added to a DUT to make it boundary scan compliant. The boundary cells allow the test data to be routed such that the DUT can be tested internally or the test data passed to other DUTs in the scan chain. The dedicated pins are connected to a test controller and are used to receive test control and data signals. The pins include a Test Clock (TCK), Test Mode Select (TMS), Test Data In (TDI), Test Data Out (TDO), and, optionally, Test Reset (TRST). The TCK and TMS pins are used for test control purposes. The TDI and TDO pins receive the data input and output signals for a scan chain, which may include a test pattern. Test patterns can be generated and analyzed automatically, via software programs. For example, a suitable test pattern can be generated by a tool such as an Automatic Test Pattern Generation (ATPG) tool or Boundary Scan Test Pattern Generation (BTPG) tool. Optionally, the DUT can have a fifth pin, TRST, for an asynchronous reset signal to the test controller.

During standard operation of the DUT, the boundary cells are inactive and allow data to be propagated through the DUT normally. The test controller can put the DUT into a test mode, in which the TDI and TDO are used to test the DUT and possibly other electronic devices and components in the scan chain. The IEEE standard for boundary scan is known as JTAG (Joint Test Access Group).

As an example of testing a DUT, FIG. 1 illustrates a conventional PCI (Peripheral Component Interconnect) bus configuration with a scan capable card 140 attached to a PCI slot 125. The conventional PCI bus configuration includes a host bridge adapter (HBA) 120 and a PCI slot 125 coupled by a PCI bus 130. One type of test that may be performed is a DC connectivity test, which detects defects such as open and short circuits along the data path in the PCI bus configuration. For example, the DC connectivity test checks for good traces on the PCI bus 130, good connection between the traces of the PCI bus 130 and the PCI slot 125, and good connection between the PCI slot 125 and the device that plugs into PCI slot 125. Scan tests are also used to perform other tests.

FIG. 1 illustrates a conventional technique for testing a PCI slot 125 and its associated data path by using a scan capable card 140 inserted into the PCI slot 125. The scan capable card 140 may be a PCI card having JTAG compliant login therein. FIG. 1 shows lines 150 providing five JTAG signals that may originate from a test controller (not shown) and interface to the HBA 120 via pins of the HBA 120. The JTAG signals can also be routed to the scan capable card 140 over the PCI bus 130. Thus, the HBA 120 and the scan capable card 140 can be used in a scan chain test. In this test, the HBA 120 can be instructed to send a test pattern over the PCI bus 130 to the PCI slot 125. For example, the test pattern may be input to the HBA 120 serially on TDI, but output by the HBA 120 in parallel such that lines of the PCI bus 130 and the PCI slot 125 are tested. The scan capable card 140 receives the test pattern from the PCI slot 125 and returns the test pattern back to the PCI slot 125. The data transfers between the PCI slot 125 and scan capable card 140 involve at least some of the pins on that data interface. However, some pins may not be testable. The test pattern is then returned to the HBA 120 via the PCI bus 130 and is routed back to the test controller (not shown) via TDO where the test pattern is analyzed. Thus, the scan capable card 140 allows a scan chain to be completed.

In some cases, the PCI card that plugs into the PCI slot will be boundary scan compliant. For example, boundary scan logic may be used to test the PCI card itself and is thus included therein. However, it may not be cost effective to put boundary scan logic into every PCI card of the computer system. Thus, some of the PCI cards may not have boundary scan logic, and thus a boundary scan loop cannot be formed along the associated data path in the fashion shown in FIG. 1. In order to test such a PCI slot and its associated data path, a scan capable PCI card that is not a part of the DUT can be inserted into the PCI slot for the purpose of testing and then removed after the test. To make this testing practical, the test scan capable card is used repeatedly to test different PCI slots. Unfortunately, the edge connectors of the test scan capable card wear with each insertion/removal from a PCI slot 125. Typically, the edge connectors last only about 100 insertions before the wear to the connector is sufficient to cause intermittent connection problems. Such intermittent connection problems will falsely cause the DUT to fail the test. Thus, to maintain accuracy, the test scan capable card must be replaced after only a relatively few tests. Replacement of the test scan capable card is expensive.

Slots other that PCI slots require testing as well. In order to use a scan capable card for a JTAG test as illustrated in FIG. 1, the computer system must be manufactured with traces to bring the JTAG scan signals into the slot. In some cases, the slot is required to have JTAG traces per accepted industry specification. For example, PCI has such as requirement. However, not all slots to be tested require JTAG support per an accepted industry standard. A manufacturer may avoid the expense of running JTAG traces to a slot that does not require them to comply with an industry standard. However, the slots without support for JTAG cannot be tested by the technique illustrated in FIG. 1. Therefore, a less convenient method of testing must be used if the slot is to be tested.

Thus, one problem with some conventional methods of and devices for testing an electronic device is the expense incurred in placing boundary scan logic into a device's card for testing the electronic device external to the card itself. Alternatively, a boundary scan compliant card that is not a part of the electronic device can be used for testing, but such cards are expensive and their connectors wear out rapidly, which adds further to the testing expense. Moreover, if the test boundary scan card is not replaced before it goes intermittent, the test of the DUT is inaccurate. A still further problem is the expense incurred in running boundary scan traces to every slot in an electronic device to support a scan test of each slot.

### DISCLOSURE OF THE INVENTION

The present invention pertains to a method and apparatus for testing an electronic device. In one embodiment, the method comprises transferring a test pattern between a first data controller coupled to a first data interface and a second data controller coupled to a second data interface via an element coupling the first and second data interfaces. The test pattern is received and examined.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 illustrates a PCI bus configuration with an attached conventional PCI card with scan support for testing the PCI bus configuration.

FIG. 2A is an illustration of a configuration adapted to test an electronic device by coupling two data interfaces that are not typically connected, according to a first embodiment of the present invention.

FIG. 2B is an illustration of a configuration adapted to test an electronic device by coupling two data interfaces that are not typically connected, according to a second embodiment of the present invention.

FIG. 3A is an illustration of a configuration adapted to test an electronic device by coupling more than two data interfaces that are not typically connected, according to a third embodiment of the present invention.

FIG. 3B is an illustration of a configuration adapted to test an electronic device by coupling more than two data interfaces that are not typically connected, according to a fourth embodiment of the present invention.

FIG. 4 is a flowchart illustrating a process of testing an electronic device by coupling at least two data interfaces, according to an embodiment of the present invention.

FIG. 5 is an exemplary platform for a computer system that may be used to implement embodiments of the present invention.

### DETAILED DESCRIPTION OF THE INVENTION

In the following detailed description of embodiments of the present invention, a method of and an apparatus for testing an electronic device, numerous specific details are set forth in order to provide a thorough understanding of the present invention. However, embodiments of the present invention may be practiced without these specific details or by using alternative elements or methods. In other instances well known methods, procedures, components, and circuits have not been described in detail as not to unnecessarily obscure aspects of the present invention.

Embodiments of the present invention provide a way to test an electronic device by bridging two data interfaces of the electronic device. The two data interfaces are not typically connected during normal operation of the electronic device. The electronic device has a first scan capable component that is able to drive scan data to one of the data interfaces and a second scan capable component that is able to receive the scan data from the other data interface such that the two scan capable components are coupled via a path between the two data interfaces. The data interfaces involved can be those used for input/output, memory, sub-systems, disks, etc. Embodiments perform the scan test without requiring scan capable support cards that insert into the data interfaces.

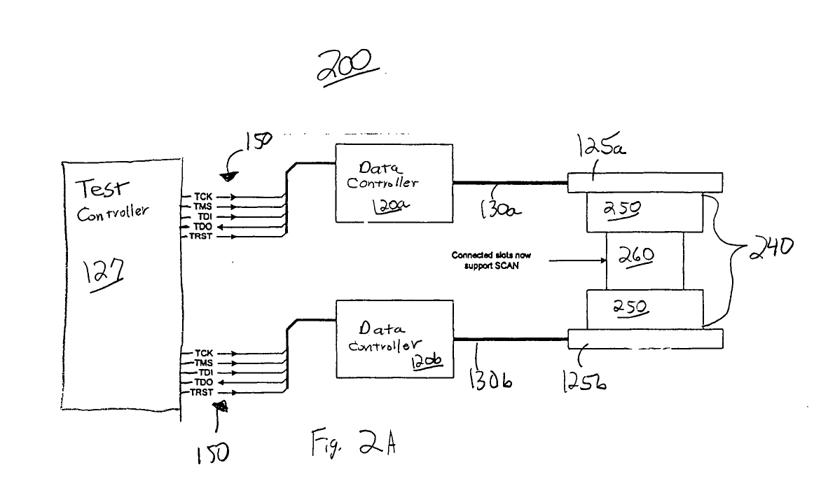

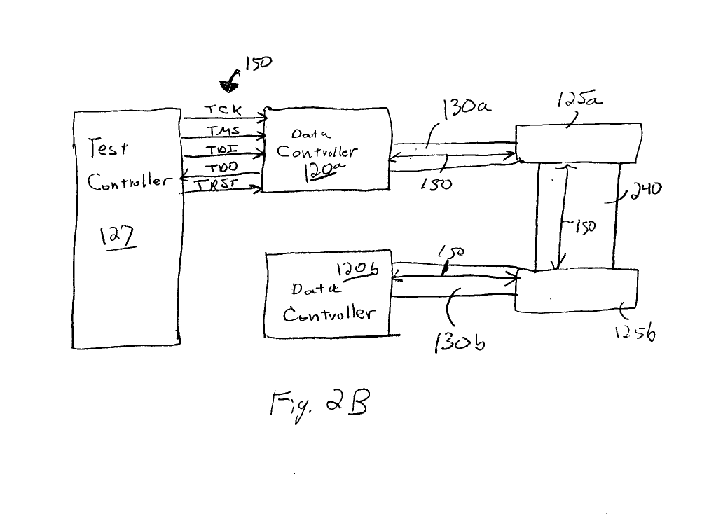

FIG. 2A is an illustration of a configuration 200 adapted to test some aspect of an electronic device by transferring scan data from a first data interface 125a to a second data interface 125b in order to couple two scan capable devices, according to an embodiment of the present invention. The test controller 127 controls the test through the various JTAG signals (TCK, TMS, TDI, TDO, TRST), in this embodiment. However, the present invention is not limited to implementing the test according to JTAG. The data controllers 120 are scan capable devices and are able to control data flow to/from the data interface 125 associated with the data controller 120. The data controllers 120 may be, but are not limited to, a memory data multiplexer (MUX), a SCSI (Small Computer Systems Interface) controller, and an HBA. The two data controllers 120 do not have to be of the same type. For example, one data controller 120 may be a memory MUX and the other data controller 120 a SCSI controller.

Still referring to the embodiment of FIG. 2A, the test controller 127 puts each data controller 120 into a test mode via lines 150 providing JTAG signals. In this embodiment, the test controller 127 has a connection to each data controller 120 through a path other than the data path 130. However, the test controller 127 can interface with the data controllers 120 in other ways. FIG. 2B illustrates an embodiment in which the test controller 127 is coupled to one data controller 120a via lines 150 providing JTAG signals. The JTAG signals are transferred over the PCI bus 130a, over coupling device 240, over PCI bus 130b to the other data controller 120b. Thus, the test controller 127 is able to control the other data controller 120b via the transmission of JTAG signals or the like over the data paths 130 and coupling device 240.

Referring again to the embodiment of FIG. 2A, the coupling device 240 includes two plug-in jumper cards 250 that form an electrical connection to respective pins or the like of the data interfaces 125. The plug-in jumper cards 250 are electrically connected together such that the pins or the like of one data interface 125 are electrically coupled to the pins or the like of the other data interface 125. However, the present invention is not limited to a coupling device 240 with a plug-in jumper card to achieve the interface with the data interface 125. In another embodiment, the coupling device 240 has a bed-of-nails test fixture to achieve the interface with the data interface 125. More generally, the coupling device 240 may include any means to achieve the interface to the data interfaces 125.

The plug-in jumper cards 250 are connected to one another via a connection 260. In one embodiment, the connection 260 is a flex circuit. In another embodiment, the connection 260 is a ribbon cable. The present invention is not limited to either of these embodiments to implement the connection 260. Any suitable means may be used to electrically couple the plug-in jumper cards 250 to one another. In one embodiment, the data interfaces 125 have the same form factor. For example, both data interfaces 125 are PCI slots. In this case, the plug-in jumper cards 250 may be PCI form factor cards. Thus, the plug-in jumper cards 250 are adapted to fit into PCI slots. However, the present invention is well suited to coupling data interfaces having a different form factor from one another. For example, one data interface 125 may be a memory slot and the other data interface 125 may be a SCSI port. In this case, the coupling device 240 is suitable to form a connection therebetween.

Referring again to the embodiment of FIG. 2A, the test controller 127 transfers a test pattern serially into data controller 120a via TDI. By using appropriate JTAG signals, the test controller 127 directs the data controller 120a to transfer the test data in parallel across the data path 130a to the first data interface 125a. The test pattern travels over the coupling device 240 to the second data interface 125b and on to the second data controller 120b via the data path 130b. The second data controller 120b sends the test pattern data back to the test controller 127, for the test controller 127 to examine. The second data controller 120b may send the test pattern directly to the test controller 127 via its TDO interface to the test controller 127. Alternatively, the second data controller 120b may send the test data back to the test controller 127 via data path 130b, coupling device 240, data path 130a, and data controller 120a. Thus, two scan capable devices are coupled by the electrical coupling of the two data interfaces 125. Such a coupling of two data interfaces 125 is non-intuitive. For example, the two data interfaces 125 may be PCI slots. It is not intuitive to couple together two separate PCI slots. As another example, the two data interfaces 125 could be a memory slot and a disk drive slot. It is not intuitive to electrically couple, for example, a memory slot to a disk drive slot.

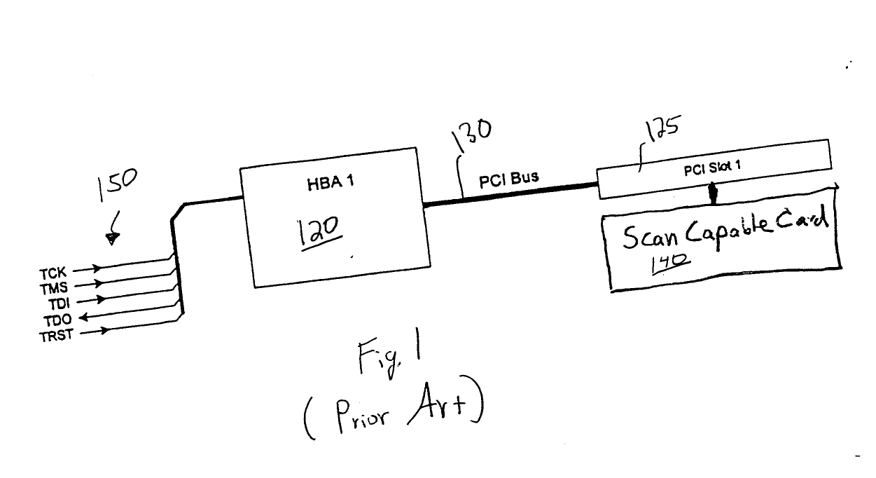

Referring now to the embodiment of FIG. 2B, scan signals are provided via lines 150 in data path 130a, data interface 125a, coupling device 240, and data path 125b. For example, JTAG signals may be routed to the data interface 125a from its data controller 120a. This allows the JTAG signals that the test controller 127 sends to one data controller 120 to be propagated to the other data controller 120 via the coupling device 240. Transferring the JTAG signals between data controllers 120 across the coupling device 240 allows for simpler testing of the data controllers 120. For example, some test controllers 127 only support one scan chain. Thus, one test controller 127 would not be able to test more than one data controller 120 using the conventional technique illustrated in FIG. 1. However, the embodiment of FIG. 2B can test multiple data controllers 120, such as HBAs, using a single scan chain. This embodiment simplifies the scan support, as a single test controller 127 supporting a single scan chain can be used to test multiple data controllers 120. Further, the present invention is not limited to the scan signals being JTAG signals.

Referring again to the embodiment of FIG. 2A, it is not required that the JTAG signals be transferred over data path 130a, data interface 125a, coupling device 240, and data path 125b. However, the JTAG signals may be transferred between the two data controllers 120a, 120b via this path. For example, in one embodiment, the data paths 130 are compliant with the PCI bus standard, which requires that JTAG signals be transferred across the PCI bus.

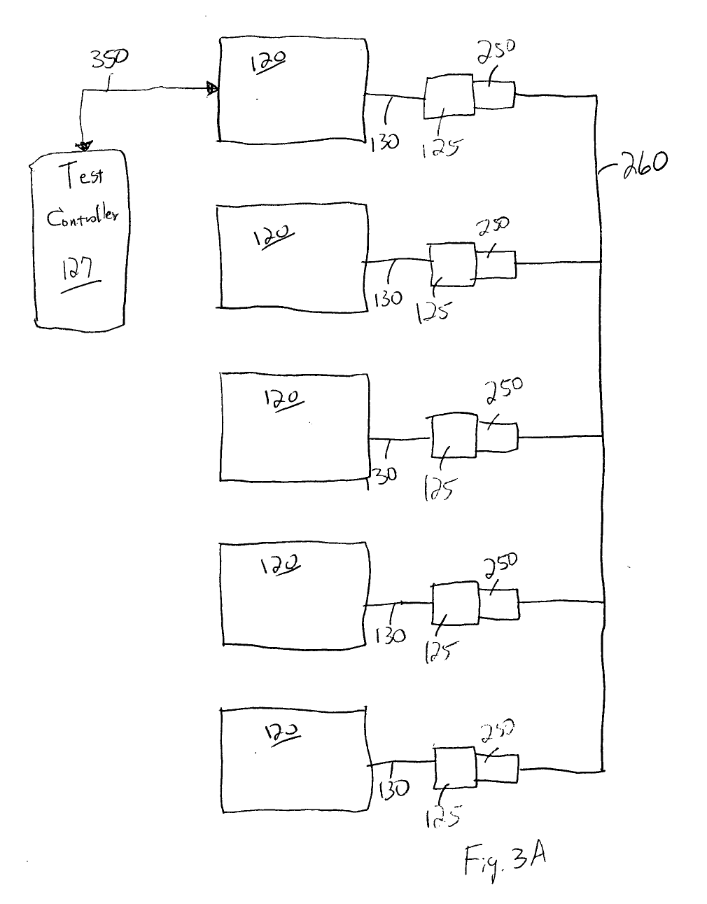

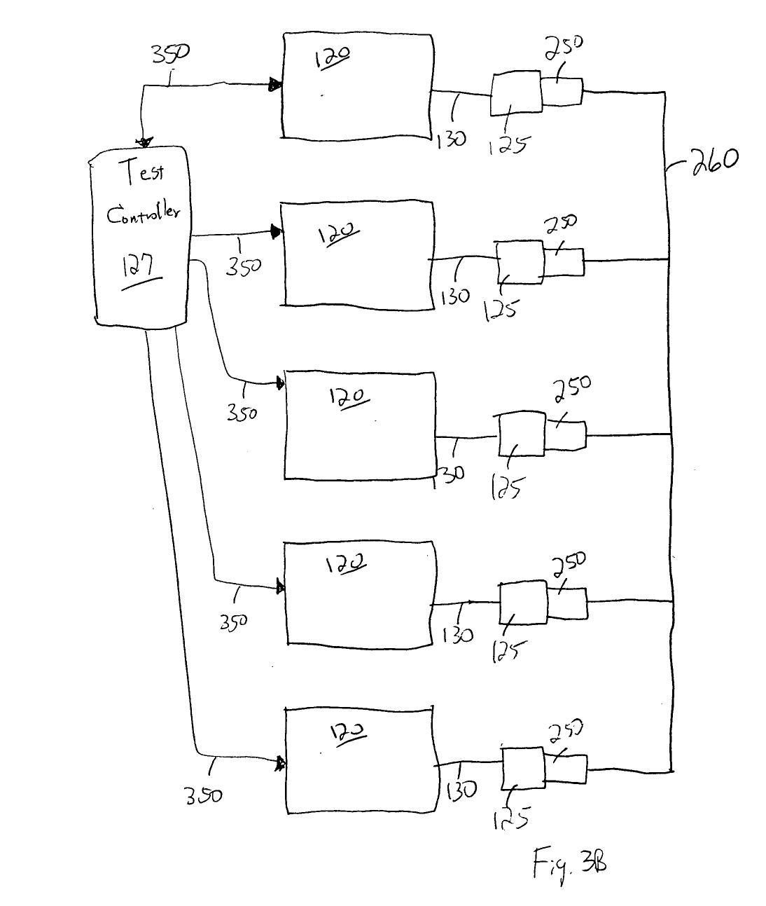

FIG. 3A illustrates an embodiment of the present invention in which portions of an electronic device are tested by electrically connecting more than two data interfaces 125 to each other. In the embodiment of FIG. 3A, each data controller 120 is scan-capable. For example, each data controller 120 is compliant with a boundary scan test of some type, such as JTAG. Each data controller 120 is coupled to a data interface 125 via a separate data bus 130. Each of the five data interfaces 125 has a card 250 inserted therein. A single connection 260 couples all five cards 250. Thus, the separate data interfaces 125 and their respective data paths 130 are electrically coupled. This coupling of the data interfaces 125 is non-intuitive, as the data path 130 associated with each data interface 125/data controller 120 combination is considered to be data path 130 that is independent of all other data interface/data controller combinations. The data controllers 120 may be, but are not limited to, a memory data MUX, a SCSI (Small Computer Systems Interface) controller, an HBA. Hence, the data interfaces 125 may be a variety of suitable form factors. The types of data interfaces 125 that are electrically coupled can be of any combination of form factors.

Still referring FIG. 3A, a single test controller 127 may control the test, in this embodiment. As illustrated in FIG. 3A, the test controller 127 sends the test control signals and test patterns over control lines 350 directly to one of the data controllers 120. The control lines 350 may be JTAG compliant traces, but the present embodiment is not limited to JTAG. That data controller 120 forwards the test control signals on to the remaining data controllers 120. When in a mode of testing one of the remaining data controllers 120, the data controller 120 connected to the test controller 127 may forward a test pattern and test control signals serially to its data interface 125. For example, the test pattern and control signals may be forwarded on TDO, TDI, TCK, and TMS, lines that are part of the data path 130. When in a mode to test the data paths 130, the data controller 120 connected to the test controller 127 may forward a test pattern in parallel over all lines of the data path 130.

FIG. 3B illustrates an alternative to the embodiment depicted in FIG. 3A. In the embodiment of FIG. 3B, the test controller 127 is coupled to each data controller 120 via lines 350 that provide JTAG signals.

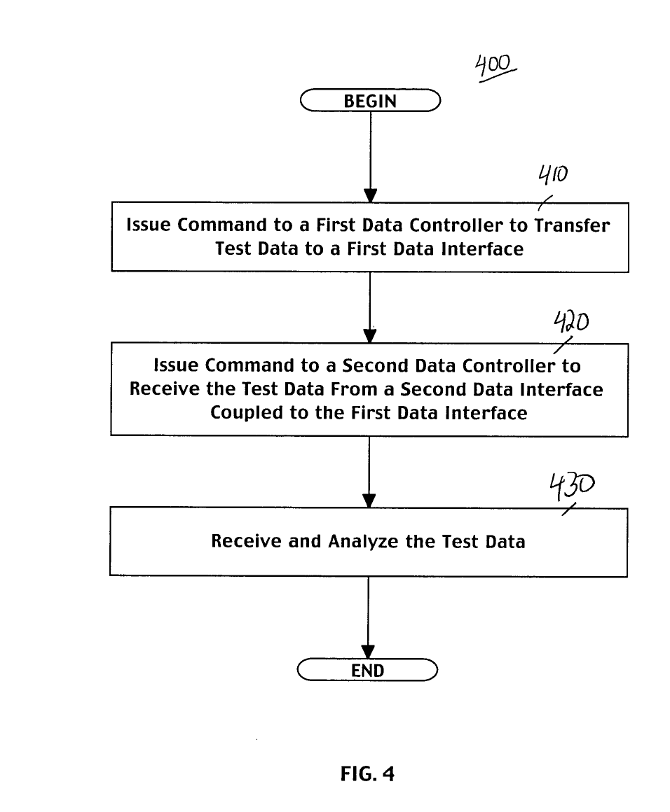

FIG. 4 illustrates a method of testing an electronic device. Steps of process 400 may be stored in a computer readable medium and executed on a general-purpose processor. Step 410 comprises issuing a command to a first data controller directing it to transfer a test pattern from the first data controller to a first data interface coupled thereto. A test controller may be used to issue the command, and in general to control the test. The test pattern may be transferred to the first controller at a later point in time. Further, the test controller will typically put the first data controller into a drive mode before issuing the command to transfer the test pattern to the first data interface.

Step 420 comprises issuing a command to a second data controller to receive the test pattern from a second data interface that is electrically coupled between the first data interface and the second data controller. The test controller will typically put the second data controller into receive mode before issuing the command to receive the test pattern. Thus, the first data controller and the second data controller are coupled via the first and second data interfaces. The data interfaces may be coupled as shown in the embodiments of FIGS. 2A, 2B, or 3; however, it is not required that one of these embodiments be used. Step 420 optionally includes issuing a command to additional data controllers to receive the test pattern from respective data interfaces coupled to the data controllers. The respective data interfaces are each coupled between the first data interface and their respective data controller.

Step 430 comprises receiving the test pattern from the second data controller. For example, the test controller may receive the test pattern on a TDO pin of the second data controller. Alternatively, the test pattern is routed back from the second data controller to the first data controller via the coupled first and second data interfaces. The first data controller then sends the test pattern to the test controller via its TDO pin. Thus, process 430 accomplishes transferring a test pattern between a first data controller coupled to a first data interface and a second data controller coupled to a second data interface via an element coupling the first and second data interfaces. The test pattern may then be analyzed. In one embodiment, the test pattern is adapted to test the electrical connectivity between the data paths and various components between the data controllers. However, the test pattern is not so limited. In another embodiment, the ID code of each data controller is verified.

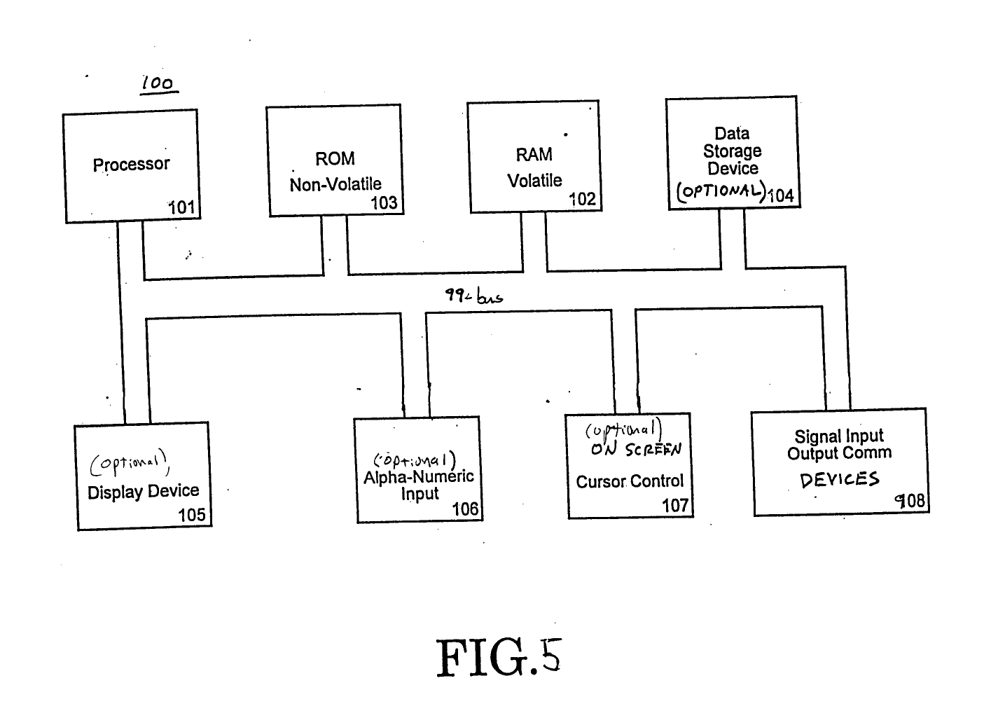

With reference now to FIG. 5, portions of embodiments of the present invention are comprised of computer-readable and computer-executable instructions that reside, for example, in computer-usable media of a computer system. FIG. 5 illustrates an exemplary computer system 100 used to perform a method in accordance with embodiments of the present invention. It is appreciated that system 100 of FIG. 5 is exemplary only. Additionally, computer system 100 of FIG. 5 is well adapted to having computer readable media such as, for example, a floppy disk, a compact disc, and the like coupled thereto. Such computer readable media is not shown coupled to computer system 100 in FIG. 5 for purposes of clarity.

System 100 of FIG. 5 includes an address/data bus 99 for communicating information, and a central processor unit 101 coupled to bus 99 for processing information and instructions. System 100 also includes data storage features such as a computer usable volatile memory 102, e.g., random access memory (RAM), coupled to bus 99 for storing information and instructions for central processor unit 101, computer usable non-volatile memory 103, e.g. read only memory (ROM), coupled to bus 99 for storing static information and instructions for the central processor unit 101, and an optional data storage unit 104 (e.g., a magnetic or optical disk and disk drive) coupled to bus 99 for storing information and instructions.

With reference still to FIG. 5, system 100 of embodiments of the present invention also includes an optional alphanumeric input device 106 including alphanumeric and function keys is coupled to bus 99 for communicating information and command selections to central processor unit 101. System 100 also optionally includes a cursor control device 107 coupled to bus 99 for communicating user input information and command selections to central processor unit 101. System 100 of the present embodiment also includes an optional display device 105 coupled to bus 99 for displaying information. Signal input/output communication device(s) 108 is also coupled to bus 99.

While the present invention has been described in particular embodiments, it should be appreciated that the present invention should not be construed as limited by such embodiments, but rather construed according to the below claims.

1. A method of testing an electronic device, said method comprising:
a) transferring a test pattern between a first data controller coupled to a first data interface and a second data controller coupled to a second data interface via an element coupling said first and second data interfaces;
b) receiving said test pattern; and
c) examining said test pattern.

2. The method of claim 1, wherein said a) further comprises:
transferring said test pattern between said first data controller and a third data controller coupled to a third data interface via an element coupled between said first data interface and said third data interface.

3. The method of claim 1, wherein said test pattern tests electrical connectivity over between said first data controller and said second data controller.

4. The method of claim 1, wherein said a) comprises transferring said test pattern over data interfaces having the same form factor.

5. The method of claim 1, wherein said a) comprises transferring said test pattern over data interfaces having different form factors from one another.

6. The method of claim 5, wherein said a) comprises transferring said test pattern over data interfaces comprising at least two of: a PCI (Peripheral Component Interconnect) interface, a memory interface, and a disk controller interface.

7. The method of claim 1, wherein said first and second data controllers are both tested using a single scan chain.

8. The method of claim 1, wherein said a) comprises:
a1) establishing a drive mode for said first data controller; and
a2) establishing a receive mode for said second data controller.

9. An apparatus for testing an electronic device, said apparatus comprising:
a first element that is operable to be inserted into a first data interface coupled to a first data path of the electronic device;
a second element that is operable to be inserted into a second data interface coupled to a second data path of the electronic device, wherein said first and second data interfaces are not typically connected during operation of the electronic device; and
a third element coupled between said first element and said second element to allow an electrical coupling of the first data interface to the second data interface, wherein said electrical coupling allows the formation of a test data path including the first and second data paths.

10. The apparatus of claim 9, further comprising:
a fourth element that is operable to be inserted into a third data interface coupled to a third data path of the electronic device; and
wherein said third element is further coupled between said first element and said fourth element to allow an electrical coupling of the first data interface to the third data interface, wherein said electrical coupling of the first data interface to the third data interface allows the formation of a test data path including the first and third data paths.

11. The apparatus of claim 9, wherein:
said first element and said second element are adapted to be inserted to data interfaces having the same form factor.

12. The apparatus of claim 9, wherein:
said first element and said second element are adapted to be inserted to data interfaces having different form factors.

13. The apparatus of claim 9, wherein:
said first element comprises a plug-in jumper card adapted to be inserted into a PCI (Peripheral Component Interconnect) card slot.

14. The apparatus of claim 13, wherein:
said second element comprises a plug-in jumper card adapted to be inserted into a PCI (Peripheral Component Interconnect) card slot.

15. The apparatus of claim 13, wherein:
said second element is adapted to be inserted into a memory slot.

16. The apparatus of claim 13, wherein:
said second element is adapted to be inserted into a disk drive slot.

17. The apparatus of claim 9, wherein said electrical coupling further allows an electrical connectivity test.

18. The apparatus of claim 9, wherein said electrical coupling further allows multiple data controllers to be tested using a single scan chain.

19. A computer readable medium having stored therein instructions that when executed on a processor implement a method of testing an electronic device, said method comprising:
issuing a command to a first data controller to transfer a test pattern from said first data controller to a first data interface coupled thereto; and
issuing a command to a second data controller to receive said test pattern from a second data interface that is electrically coupled between said first data interface and said second data controller; and
receiving said test pattern.

20. The computer readable medium of claim 19, wherein said method further comprises:
issuing a command to a third data controller to receive said test pattern from a third data interface that is electrically coupled between said third data controller and said first data interface.

21. The computer readable medium of claim 19, wherein said method further comprises determining that a data path exists from said first data controller to said second data controller through a path including said first and second data interfaces.

22. The computer readable medium of claim 19, wherein said method further comprises testing a plurality of data controllers using a single scan chain.

23. The computer readable medium of claim 19, wherein said method further comprises performing an electrical connectivity test of a data path comprising said first data interface and said second data interface.
